(19) United States
(12) Patent Application Publication
(10) Pub. No.: US 2003/0106986 A1
(43) Pub. Date: Jun. 12, 2003

(54) Low dark current CMOS image sensor cell and array layout

(76) Inventors: Hsiu-Yu Cheng, Kaohsiung Hsien (TW); Ya-Chin King, Chungli (TW)

Correspondence Address: J.C. Patents, Inc., Suite 250, 4 Venture, Irvine, CA, 92618, US

(21) Appl. No.: 10/082,043

(22) Filed: Feb. 20, 2002

(30) Foreign Application Priority Data
Dec. 7, 2001 (TW) 90130291

(51) Int. Cl. H01L 27/00

(52) U.S. Cl. 250/208.1

(57) ABSTRACT

A complementary metal-oxide-semiconductor image sensor structure and associated layout method. A gate polysilicon layer of a reset transistor isolates the illumination region of an optical diode from field oxide layer corners of the image sensor so that current leaks between the illumination region and field oxide layer corners are minimized. Each side of the polysilicon layer also extends to and connects with a neighboring polysilicon layer. This expands the illumination region and increases fill factor of the layout.

### CROSS-REFERENCE TO RELATED APPLICATION This application claims the priority benefit of Taiwan application serial no. 90130291, filed Dec. 7, 2001.

### BACKGROUND OF THE INVENTION

1. Field of Invention

The present invention relates to a complementary metal-oxide-semiconductor (CMOS) image sensor cell and array layout. More particularly, the present invention relates to a low dark current CMOS image sensor cell and array layout.

2. Description of Related Art

Images and pictures are the most convenient medium for communicating information between people. Due to the importance of images and pictures, efforts are made for recognizing and preserving images. At present, a large variety of imaging devices and related equipment are up in the market. Examples of imaging devices include hand-held color cameras, anti-theft black-and-white monitors, digital cameras, facsimiles and medical sensors. Most of these image-processing devices rely on image sensors to perform their function. Since complementary metal-oxide-semiconductor (CMOS) image sensors have advantageous properties including high stability, high sensitivity, low operating voltage, low power consumption, high reactance and immunity to strong magnetic field, CMOS sensors are widely adopted. However, CMOS sensors do have some disadvantages compared with charge-coupled devices (CCDs). Although CMOS sensors are relatively inexpensive and may form a system-on-chip (SOC) package by integrating the sensors with control circuits, analogue-to-digital circuits and digital signal processing circuits on a single chip, the production of a relatively high dark current renders the CMOS sensor useless in a low illumination environment. Furthermore, prolonged exposure of the CMOS sensors to light will not improve the ultimate quality of the image.

### SUMMARY OF THE INVENTION

Accordingly, one object of the present invention is to provide a complementary metal-oxide-semiconductor (CMOS) image sensor for reducing dark current and an array layout associated with the CMOS image sensor for increasing fill factor.

To achieve these and other advantages and in accordance with the purpose of the invention, as embodied and broadly described herein, the invention provides a CMOS image sensor structure. The structure includes an optical diode, a reset transistor, a source follower transistor and an output selection transistor. The optical diode receives light from a light source. An optical diode voltage is produced according to the strength of the light source. Various studies have concluded that area around the illumination region and the interfaces with field oxide corners are major sources of current leak in an optical diode. Hence, in this invention, the polysilicon gate of the reset transistor surrounds the illumination region of the optical diode so that the illumination region is separated from the field oxide corners and hence dark current of the optical diode is reduced. The reset transistor serves to reset the optical diode voltage to a reset level. The source follower transistor provides an output current of the optical diode so that the optical diode voltage may be read. The output selection transistor is a device that chooses whether to read out the voltage of the illuminated optical diode and determine the strength of illumination.

This invention also provides a layout for a CMOS image sensor capable of reducing dark current. The image sensor includes an optical diode, a reset transistor, a source follower transistor and an output selection transistor. The optical diode receives light from a light source. An optical diode voltage is produced according to the strength of the light source. The reset transistor serves to reset the optical diode voltage to a reset level. The source follower transistor provides an output current from the optical diode so that the optical diode voltage may be read. The output selection transistor is a device that chooses whether to read out the voltage of the illuminated optical diode and determine the strength of illumination. The gate polysilicon of the reset transistor surrounds the illumination region of the optical diode and separates the illumination region from field oxide corners. Furthermore, the gate polysilicon on each side extends to the gate polysilicon of neighboring pixels so that the illumination region is widened and fill factor of the layout is increased.

Since region surrounding the illumination region and the interfaces with field oxide corners are major areas of current leaks in an optical diode, isolating the illumination region and the field oxide corners is an effective means of reducing dark current in a CMOS image sensor.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a schematic top view of a conventional CMOS image sensor;

FIG. 1B is a cross-sectional view along line A-A′ of FIG. 1A;

FIG. 2A is a schematic top view of a CMOS image sensor according to one preferred embodiment of this invention;

FIG. 2B is a cross-sectional view along line A-A′ of FIG. 2A; and

FIG. 3 is a schematic top view of a 3×3 CMOS image sensor array according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

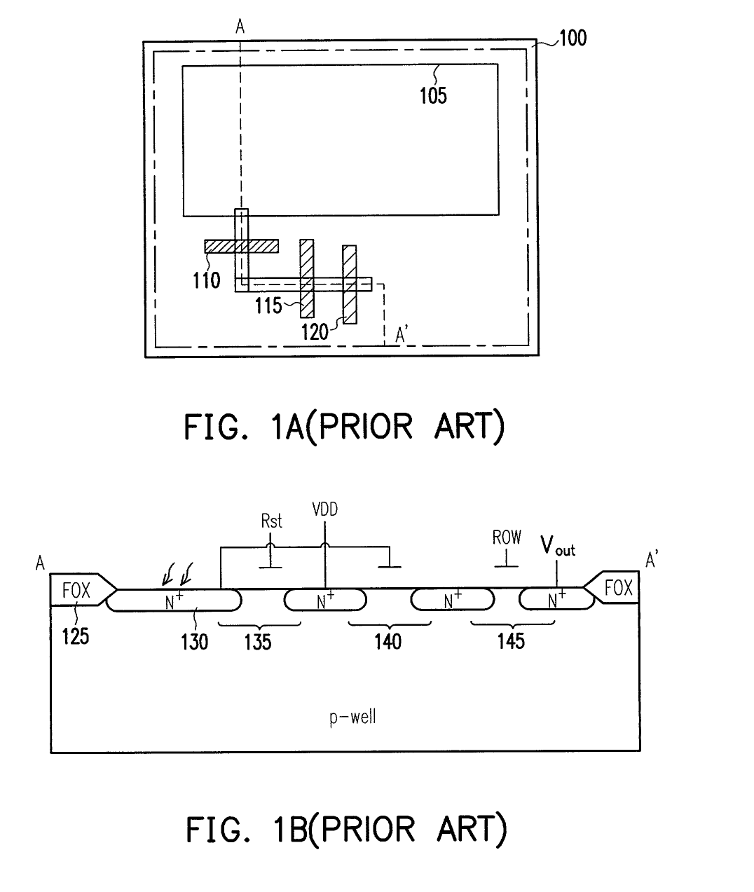

FIG. 1A is a schematic top view of a conventional CMOS image sensor. FIG. 1B is a cross-sectional view along line A-A′ of FIG. 1A. As shown in FIGS. 11A and 11B, the image sensor 100 comprises an optical diode 130 and surrounding illumination region 105, a reset transistor (110, 135), a source follower transistor (115, 140) and an output selection transistor (120, 145). To operate the image sensor, the reset transistor 135 is switched on so that voltage of the optical diode 130 is reset to a reset level. Optical diode voltage drops when the optical diode 130 is illuminated. At the end of an exposure period, the output selection transistor 145 is switched on so that the optical diode voltage is transmitted to read-out circuit driven by the source follower transistor 140. Since the extent of the voltage drop in the optical diode 130 is related the strength of the illuminating source, strength of the light source can be determined. However, voltage drop in the optical diode 130 is also influenced by the amount of dark current flowing within the optical diode 130. Various studies have shown that the illumination region surrounding an optical diode and interface region with field oxide layer 125 corner are major areas where leakage current are produced. Hence, a conventional CMOS image sensor may generate lots of undesirable noise even in the absence of any illumination due to the presence of a dark current.

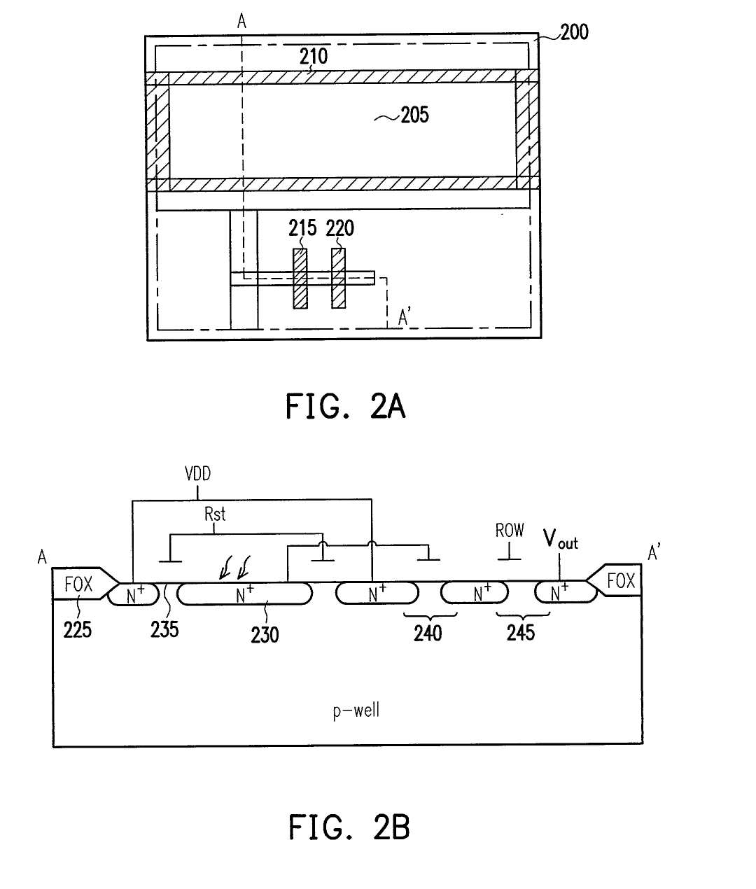

FIG. 2A is a schematic top view of a CMOS image sensor according to one preferred embodiment of this invention. FIG. 2B is a cross-sectional view along line A-A′ of FIG. 2A. As shown in FIGS. 2A and 2B, the image sensor 200 comprises an optical diode 230 and associated illumination region 205, a reset transistor (210, 235), a source follower transistor (215, 240) and an output selection transistor (220, 245). The illumination region 205 of the optical diode 230 is surrounded by rectangular-shaped gate polysilicon of the reset transistor (210, 235) so that the surrounding area of the illumination region 205 and field oxide corners 225 are completely isolated. Hence, there is a reduction in dark current and an increase in image-sensing capability and permitted exposure period.

The CMOS image sensor according to the embodiment of this invention employs a 0.35 μm line width production process and each pixel occupies an area of about 7.5 μm×7.5 μm. As shown in FIGS. 2A and 2B, each side of the gate polysilicon of the reset transistor (210, 235) that surrounds the illumination region 205 of the optical diode 230 extends to the common boundary with neighboring devices. Because the gate of the reset transistor (210, 235) is connected to a reset control signal terminal and the resetting operation is carried out concurrently, the gate polysilicon of all reset transistors (210, 235) belonging to a single row may be connected together. Ultimately, the illumination region 205 is expanded.

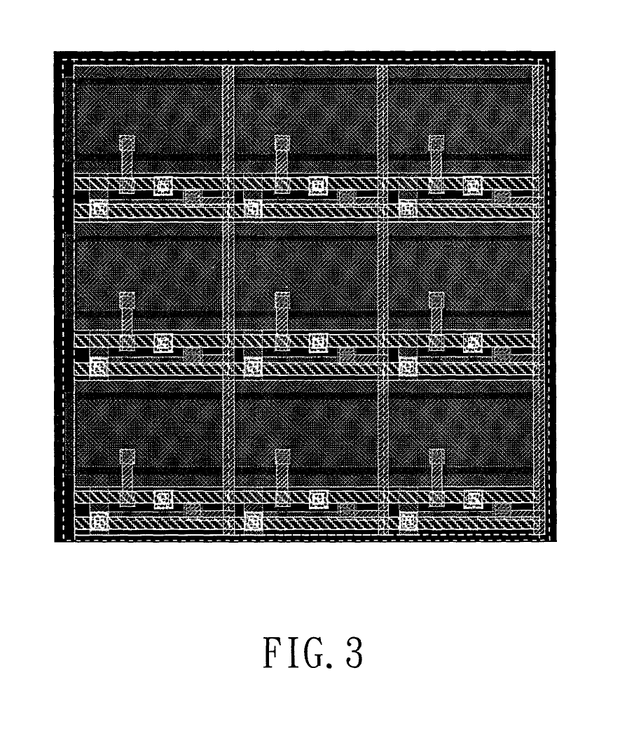

FIG. 3 is a schematic top view of a 3×3 CMOS image sensor array according to one preferred embodiment of this invention. The fill factor of a conventional sensor layout is only about 35%. With the sensor layout shown in FIG. 3, a fill factor of about 41% is produced. Hence, the layout according to this invention is able not only to reduce the dark current flowing within the sensor, but is also able to increase the fill factor as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A complementary metal-oxide-semiconductor (CMOS) structure for reducing dark current, comprising:
an optical diode for receiving a beam of light from a light source and producing a diode voltage according to the strength of the light beam, wherein a polysilicon layer isolates an illumination region of the optical diode from field oxide layer corners of the images sensor;
a reset transistor for resetting the diode voltage to a reset level;
a source follower transistor for providing an output current from the diode so that the diode voltage may be read; and
an output selection transistor for choosing whether to read out the diode voltage or not.

2. The CMOS structure of claim 1, wherein the polysilicon layer is a gate terminal of the reset transistor.

3. The CMOS structure of claim 2, wherein the polysilicon layer forms a rectangular enclosure around the illumination region.

4. The CMOS structure of claim 3, wherein each side of the polysilicon layer extends to neighboring pixels so that the polysilicon layer and their neighboring polysilicon layer are connected and used together.

5. The CMOS structure of claim 4, wherein the image sensor pixel is fabricated using 0.35 μm technique with an area size of 7.5 μm×7.5 μm.

6. A complementary metal-oxide-semiconductor (CMOS) image sensor layout for reducing dark current, the image sensor comprising:
an optical diode for receiving a light beam from a light source and producing a diode voltage according to strength of the light beam; and
a reset transistor for resetting the diode voltage to a reset level, wherein a gate polysilicon layer of the reset transistor is used to isolate the illumination region of the optical diode and field oxide layer corners of the image sensor.

7. The CMOS image sensor layout of claim 6, wherein each side of the polysilicon layer extends to neighboring pixels so that the polysilicon layer and their neighboring polysilicon layer are connected and used together.
